(19) United States
(12) Patent Application Publication
(10) Pub. No.: US 2026/0123408 A1
(43) Pub. Date: Apr. 30, 2026

(54) ELECTRONIC DEVICE COOLING WITH INTEGRATED MAGNETICS

(71) Applicant: Texas Instruments Incorporated, Dallas, TX (US)

(72) Inventors: John Carlo Molina, Limay (PH); Jason Colte, La Trinidad (PH); Osvaldo Lopez, Annandale, NJ (US)

(21) Appl. No.: 18/933,554

(22) Filed: Oct. 31, 2024

(51) Int. Cl. H01L 23/367; H01L 21/48; H01L 21/56; H01L 23/00; H01L 23/31; H01L 23/498; H01L 23/64; H01L 25/065

(52) U.S. Cl. CPC H10W 40/22; H10W 44/501; H10W 70/02; H10W 70/093; H10W 74/016; H10W 74/114; H10W 90/00; H10W 90/701; H10W 72/07236; H10W 74/40; H10W 90/724

(57) ABSTRACT

An electronic device includes a semiconductor die having a first side attached to a substrate, a first plate having a first portion attached to a second side of the semiconductor die and a second portion extending from the first portion away from the semiconductor die, a metal clip having a second clip portion coupled to a first conductive feature of the substrate, a third clip portion coupled to a second conductive feature of the substrate, and a first clip portion above and spaced apart from the first portion of the first plate that extends between the second and third clip portions, a magnetic molding compound package structure enclosing the metal clip, the semiconductor die, and the first portion of the first plate, and a second plate exposed outside the package structure and thermally coupled to the second portion of the first plate.

### BACKGROUND

Power modules and communications devices with integrated magnetics, such as transformer windings and/or inductor coils are used for a variety of applications. Inductors and transformer components often require good thermal performance which typically depends on module thickness. However, compact system designs call for higher levels of integration along with small package size, which can challenge thermal device performance.

### SUMMARY

In one aspect, an electronic device includes a semiconductor die with a first side attached to a substrate, a first plate with a first portion attached to the semiconductor die and a second portion extending from the first portion away from the semiconductor die. A metal clip having first, second and third portions is spaced apart from the first plate, with the second and third clip portions coupled respective conductive feature of the substrate, and the first clip portion extend between the second and third clip portions above the first portion of the first plate. A package structure including magnetic molding compound encloses the metal clip, the semiconductor die, and the first portion of the first plate, and a second plate at least partially exposed outside the package structure is thermally coupled to the second portion of the first plate.

In another aspect, a system includes a circuit board having a conductive trace and an electronic device with a lead electrically coupled to the conductive trace of the circuit board. The electronic device includes a substrate having opposite first and second sides, the lead along the first side of the substrate, and conductive features along the second side of the substrate. A semiconductor die has a first side attached to the second side of the substrate, a first plate with a first portion attached to the semiconductor die, and a second portion extending from the first portion away from the semiconductor die. A metal clip having first, second and third portions is spaced apart from the first plate, with the second and third clip portions coupled respective conductive feature of the substrate, and the first clip portion extend between the second and third clip portions above the first portion of the first plate. A package structure including magnetic molding compound encloses the metal clip, the semiconductor die, and the first portion of the first plate, and a second plate at least partially exposed outside the package structure is thermally coupled to the second portion of the first plate.

In a further aspect, a method of fabricating an electronic device includes attaching a first side of a semiconductor die to a substrate, attaching a first portion of a first plate to an opposite second side of the semiconductor die with a second portion of the first plate extending from the first portion away from the semiconductor die, attaching second and third clip portions of a metal clip to respective conductive features of the substrate with a first clip portion of the metal clip above and spaced apart from the first portion of the first plate and the first clip portion extending between the second and third clip portions, forming a package structure including magnetic molding compound that encloses the metal clip, the semiconductor die, and the first portion of the first plate, removing a portion of the package structure to expose the second portion of the first plate, and thermally coupling a second plate to an exposed surface of the second portion of the first plate with a portion of the second plate at least partially exposed outside the package structure.

### BRIEF DESCRIPTION OF THE DRAWINGS

FIG. 1 is a sectional side elevation view of an electronic device taken along line 1-1 in FIGS. 1A-1D.

FIG. 1A is a sectional top view of the electronic device taken along line 1A-1A in FIG. 1.

FIG. 1B is a sectional top view of the electronic device taken along line 1B-1B in FIG. 1.

FIG. 1C is a sectional top view of the electronic device taken along line 1C-1C in FIG. 1.

FIG. 1D is a top perspective view of the electronic device of FIGS. 1-1C.

FIG. 1E is a sectional side elevation view of the electronic device taken along line 1E-1E in FIGS. 1A-1C.

FIG. 2 is a flow diagram of a method of fabricating an electronic device.

FIGS. 3-16 are partial side elevation and top views of the electronic device of FIGS. 1-1E undergoing fabrication processing according to an implementation of the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. The example structures include layers or materials described as over or on another layer or material, which can be a layer or material directly on and contacting the other layer or material where other materials, such as impurities or artifacts or remnant materials from fabrication processing may be present between the layer or material and the other layer or material.

Unless otherwise stated, “about,” “approximately,” or “substantially” preceding a value means +/−10 percent of the stated value. One or more structures, features, aspects, components, etc., may be referred to herein as first, second, third, etc., such as first and second terminals, etc., for case of description in connection with a particular drawing, where such are not to be construed as limiting with respect to the claims. Various disclosed structures and methods of the present disclosure may be beneficially applied to manufacturing an electronic device such as an integrated circuit. While such examples may be expected to provide various improvements, no particular result is a requirement of the present disclosure unless explicitly recited in a particular claim.

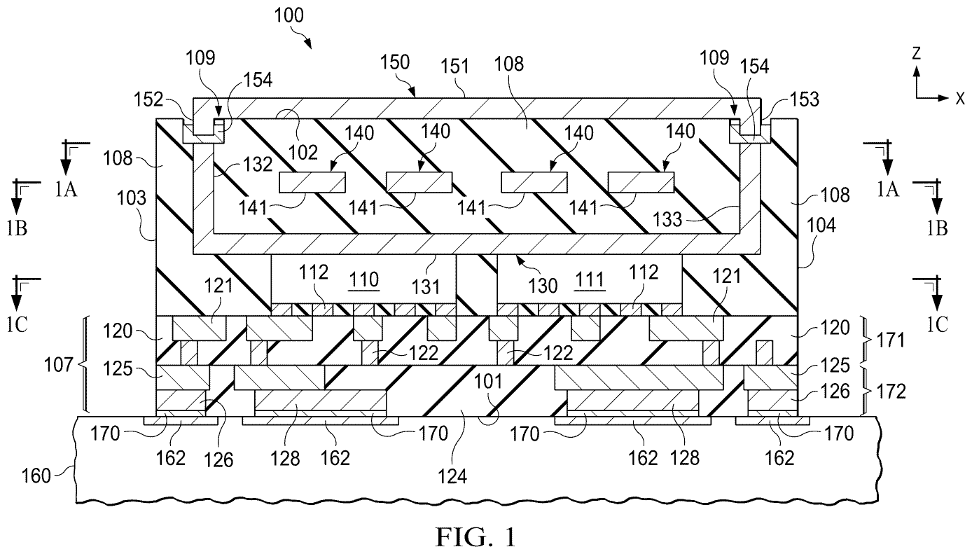

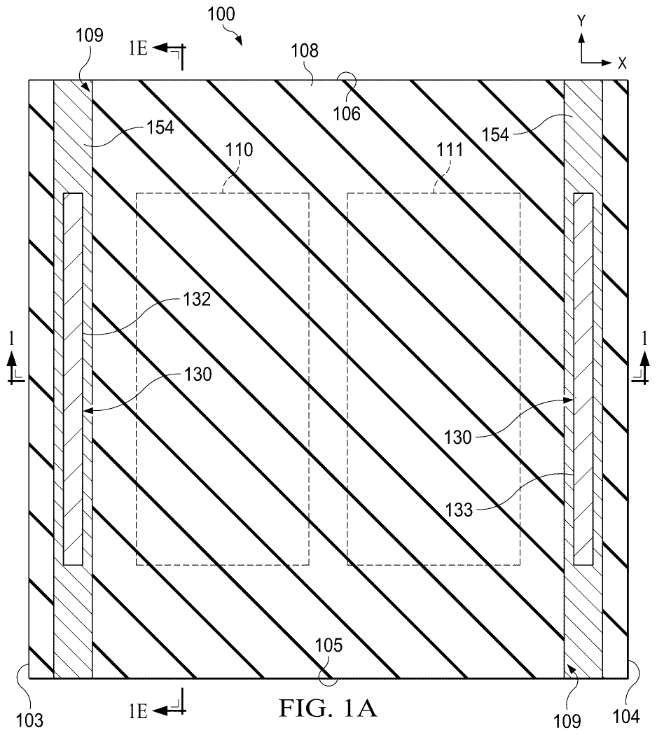

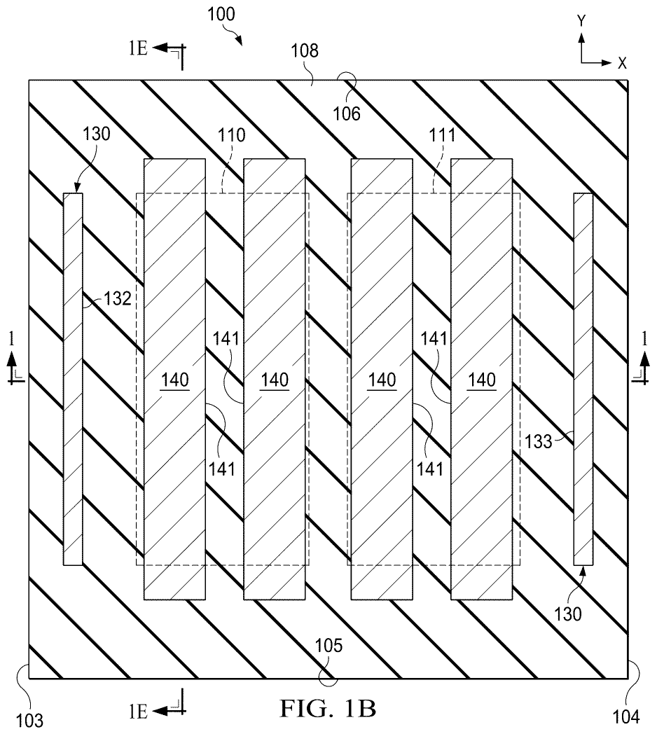

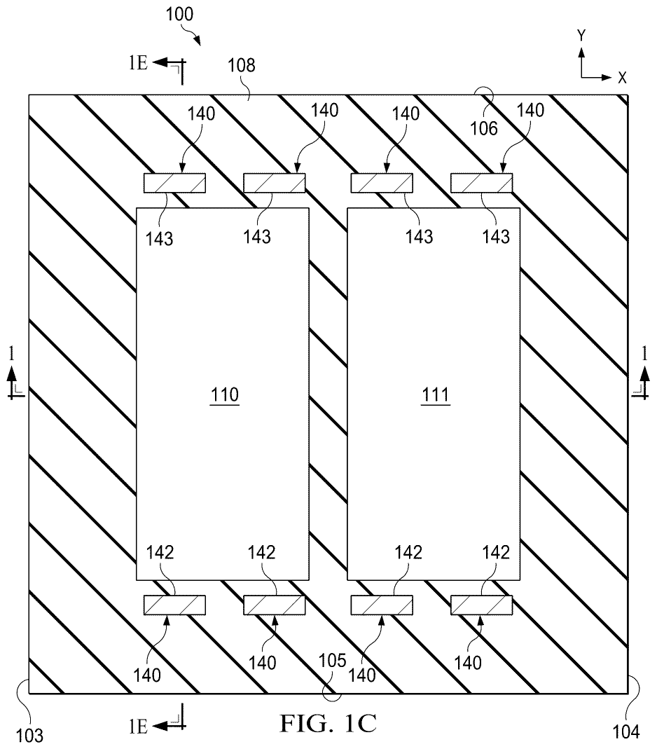

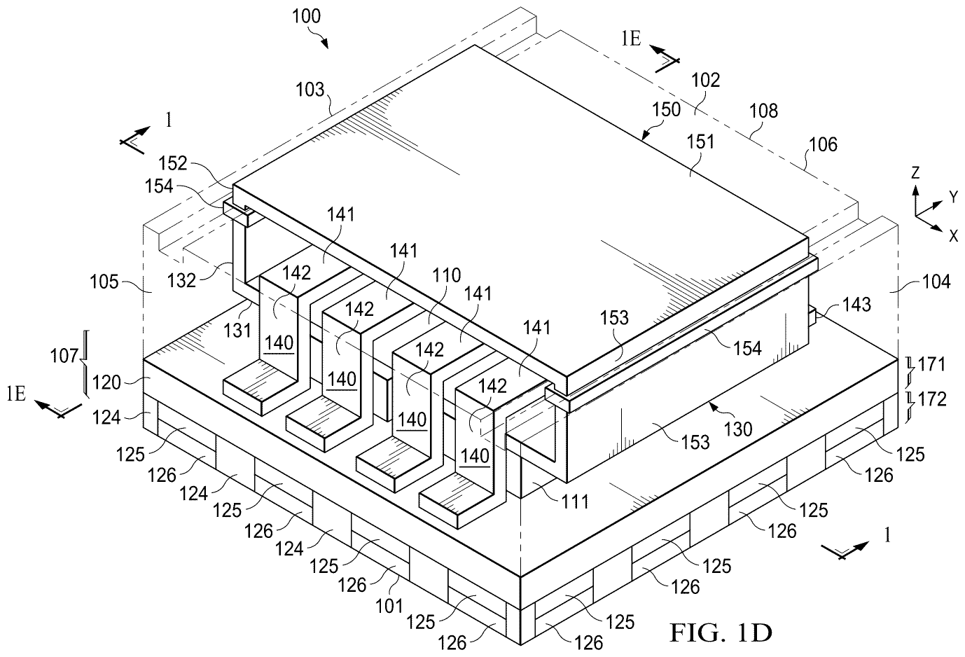

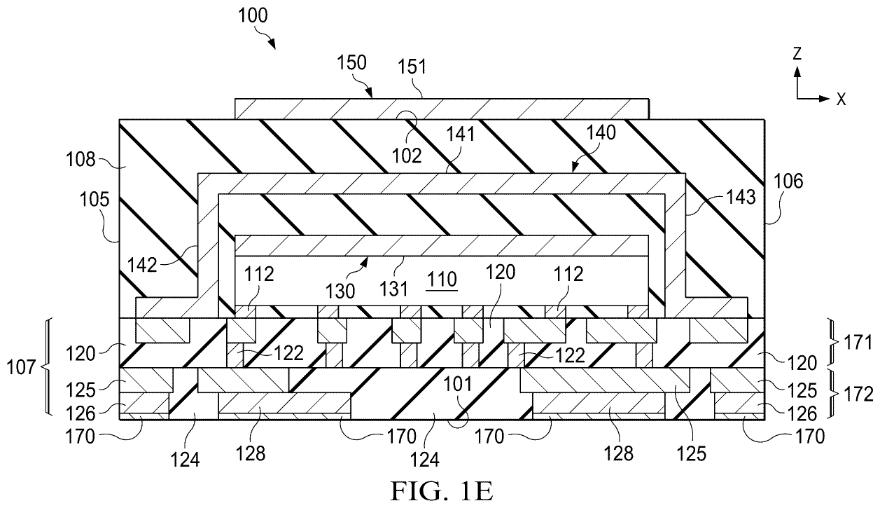

FIGS. 1-1E show a compact electronic device 100 with integrated magnetics and improved heat removal features for good thermal performance. The electronic device 100 provides topside cooling by an exposed upper plate 150 (also referred to as a second plate) for heat dissipation to an ambient environment alone or in combination with an installed heat sink (not shown). The top plate 150 is thermally coupled to a lower plate 130 (also referred to as a first plate) to provide a heat removal path from top sides of semiconductor dies 110 and 111 attached to a substrate 107. The electronic device 100 also includes metal clips 140 electrically coupled to substrate features and configured to provide an integrated inductor or transformer inside a package structure 108 that includes magnetic molding compound (MMC). The electronic device 100 advantageously provides a compact system solution with a high level of integration in good power density along with small package size while facilitating good thermal device performance to reduce or minimize die temperature and the junction to ambient temperature difference (theta-ja). In addition, the electronic device and fabrication techniques described hereinafter facilitate low cost manufacturability with integration of cooling structures and on-board magnetic components.

The example electronic device 100 can also include additional surface mount components (not shown), for example, one or more capacitors, resistors, diode, etc. mounted on and electrically coupled to the substrate 107. In one example, the substrate 107 is a multilevel package substrate (also referred to as a routable lead frame) with leads and may also include split pads of a bottom level. The multilevel package substrate 107 has leads 126 and split pads 128 for electrical connectivity to a host circuit board, such as by soldering or socket connection. In one example, the multilevel package substrate 107 provides a no-lead package form, such as a quad flat no-lead (QFN) shape with leads 126 extending on four lateral sides and exposed along a bottom side. In one implementation, the QFN package can include one or more split pads exposed along the bottom side and spaced inward from lateral sides of the device. In another implementation, the multilevel package substrate 107 includes leads in a land grid array (LGA) form configured for soldering to a circuit board or insertion into a corresponding socket of a host system. Other lead configurations and package styles are possible in other examples.

The electronic device 100 is shown in an example three-dimensional space with a first direction X, a perpendicular (orthogonal) second direction Y (FIGS. 1A and 1B), and a third direction Z (FIG. 1) that is perpendicular (orthogonal) to the respective first and second directions X and Y. Structures or features along any two of these directions are orthogonal to one another. The electronic device 100 has opposite first and second sides 101 and 102 (e.g., bottom and top), respectively, which are spaced apart from one another along the third direction Z in the illustrated position (FIGS. 1, 1D and 1E). The electronic device 100 also has laterally opposite third and fourth sides 103 and 104 (FIGS. 1-1D) that are spaced apart from one another along the first direction X, and fifth and sixth sides 105 and 106 (FIGS. 1A-1E) that are spaced apart from one another along the second direction Y in the illustrated position.

The electronic device 100 includes a multilevel package substrate 107 (FIGS. 1, 1D, 1E) and first and second semiconductor dies 111 and 112 (FIGS. 1 and 1C-1E), respectively. In one example, the electronic device 100 is a compact power module with a DC to DC converter circuit having first and second switching transistors in the respective first and second semiconductor dies 111 and 112 and connected in a half-bridge arrangement, as well as an inductor formed by the metal clips 140 and conductive interconnections of the substrate 107. The transistors of the respective semiconductor dies 110 and 111 can be any suitable technology, such as silicon-based field effect transistors (FETs), gallium nitride (GaN) transistors, bipolar transistors, etc.

A package structure 108 at least partially encloses the semiconductor dies 110 and 111, a top portion of the substrate 107, the first plate 130, and the metal clips 140. The package structure in one example is a molded structure that includes magnetic molding compound (MMC). The semiconductor dies 110 and 111 each have conductive terminals 112, such as copper pillars extending downward from bond pads of the semiconductor dies 110 and 111 and are flip chip soldered to corresponding conductive metal features along the top side of the substrate 107. In another example, the conductive terminals 112 of the semiconductor dies 110 and 111 can be electrically coupled with conductive features of the substrate 107 by other suitable means, such as conductive adhesive, bond wires (not shown), etc.

As best shown in FIGS. 1 and 1E, the multilevel package substrate 107 has a first dielectric 120 with conductive metal first trace features 121 and conductive metal first via features 122 in a top level 171. In the illustrated example, the trace features 121 and the via features 122 are or include copper and are formed by electroplating. In other examples, different conductive metals can be used. As shown in FIGS. 1, 1D and 1E, a second level 172 (e.g., the bottom level in the example two-level substrate 107) has a second dielectric 124 with conductive metal second trace features 125 and conductive metal second via features 126. The via features include conductive leads 126 that are exposed along the side 101 of the electronic device 100.

The bottom level 172 in one example also includes conductive split pads 128 that are spaced apart from the conductive leads 126. The conductive split pads 128 in one example are electrically isolated from one another and from other conductive features and are exposed along the first side 101 of the electronic device 100. In one example, the trace features 125, the split pads 128, the via features and the leads 126 of the second level 172 are or include copper and are formed by electroplating. The electronic device 100 can include raised studs on the top level 171 of the multilevel package substrate 107, for example, to provide extensions to which the conductive terminals 112 of the semiconductor dies 110 and 111 may be attached. In another example, the raised studs can be omitted. In other implementations, the multilevel package substrate 107 can include further intermediate levels (not shown) between the top level 171 and the bottom level 172.

In one example, the conductive leads 126 and the conductive split pads 128 can have a plated surface 170 exposed along the first side 101 of the electronic device 100 (e.g., FIGS. 1 and 1E). In the illustrated example, the conductive terminals 112 of the semiconductor dies 110 and 111 are soldered to corresponding pads 121 of the top level 171 of the multilevel package substrate 107 (or to any conductive raised studs (not shown), for example, by flip chip soldering.

The package structure 108 in one example includes a magnetic material, such as a magnetic mold compound with embedded magnetic particles in a molded plastic structure. Magnetic molding compound or material surrounding or proximate to a portion of the metal clips 140 can provide a magnetic field or flux path to assist operation of an inductor or transformer of the semiconductor die 110. The illustrated example includes four conductive metal clips 140, each having respective ends coupled by solder connections to corresponding conductive features of the top side of the top level 171 of the substrate 107. The substrate 107 includes connections to the respective ends of the metal clips 140 as well as conductive routing features (e.g., copper or other metal traces and/or vias) in one or both levels 171 and/or 172 to interconnect the four example metal clips 140 in series with one another to form an inductor coil, where each metal clip 140 forms a portion of a turn of the inductor. In another example, any number of one or more metal clips 140 can be included.

The substrate 107 in one example also includes connections between one end of the inductor coil and transformer terminals of each of the semiconductor dies 110 and 111. For example, one implementation of the substrate 107 includes interconnections of one end of the inductor coil to a source of a high side transistor of the first semiconductor die 110 and to a drain of a low side transistor of the second semiconductor die 111 to form a switching node. The substrate 107 further includes suitable interconnections to corresponding leads 126 of the second level 172 for the second end of the inductor coil and to other transistor terminals of the semiconductor dies 110 and 111 to form a half bridge switching circuit that can be configured for a variety of different DC to DC converter arrangements (e.g., buck, boost, buck-boost, CUK, etc.).

In another non-limiting example, the metal clips 140 can be configured by routing and connections of the substrate 107 to implement an integrated transformer, for example, with one, two or three of the metal clips 140 connected in series with one another to form a first transformer winding (e.g., a transformer primary winding) and the remaining metal clip or clips 140 connected to form a second transformer winding (e.g., a transformer secondary winding), with the magnetic molding compound of the package structure 108 providing transformer coupling between the first and second transformer windings. This arrangement can be used in a variety of isolation applications, for example, in a switching power supply device or module with an on-board isolation transformer and switching transistors of the semiconductor devices 110 and/or 111.

The multilevel package substrate 107 facilitates design flexibility regarding performance of a power converter or other circuit topology while reducing overall device size and allowing inclusion of additional (e.g., surface mount) components (not shown) and higher I/O count (e.g., device pin count) as well as the possibility of having interior isolated split pads 128. The integrated metal clip or clips 140 facilitate compact on-board magnetics for power conversion, isolated communications, or other system applications in a compact package.

The individual metal clips 140 in one example are contiguous U-shaped metal structures (e.g., conductive metal structures that are or include copper, aluminum, etc.). Each metal clip 140 has a first clip portion 141 (FIGS. 1, 1B, 1D and 1E), as well as a second clip portion 142 and a third clip portion 143 (FIGS. 1C-1E). The second and third clip portions 142 and 143 in the illustrated example each have outwardly extending landing pads or feet at each end (e.g., FIGS. 1D and 1E). As best shown in FIG. 1E, the landing pad of the second clip portion 142 is electrically coupled to a first conductive feature 121 of the substrate 107 and the landing pad of the third clip portion 143 is electrically coupled to a second conductive feature 121 of the top level 171 of the substrate 107. The interconnections and routing features of the substrate 107 provide coupling of the metal clips 140 to one another in a series configuration to form an inductor in the electronic device 100.

The first clip portion 141 extends above the first portion 131 of the first plate 130, and the first clip portion 141 is spaced apart from the first portion 131 of the first plate 130 along the third direction Z. In addition, the first clip portion 141 extends between the second and third clip portions 142 and 143 along the second direction Y (e.g., FIG. 1E). As best shown in FIGS. 1 and 1D, the first clip portion 141 of each metal clip 140 is spaced apart from and extends between the upwardly positioned U-shaped first plate 130 and the downwardly positioned U-shaped second plate 150, and the individual first clip portions 141 are each surrounded (e.g., encircle) by magnetic molding compound of the package structure 108.

In addition to integrated magnetics, the electronic device 100 provides thermal performance enhancements including heat extraction from the semiconductor dies 110 and 111 through the bottom or lower first plate 130 (FIGS. 1-1B, 1D and 1E) and the upper or second metal plate 150 (FIGS. 1, 1D and 1E). The bottom or first sides of the semiconductor dies 110 and 111 are attached to the top side of the substrate 107. The bottom or first plate 130 has a first portion 131 and a second portion 132. The first portion 131 of the first plate 130 is attached and thermally coupled to the top or second sides of the semiconductor dies 110 and 111. In one example, the first portion 131 of the first plate 130 is also electrically coupled to the top or second sides of the semiconductor dies 110 and 111. In one example, the semiconductor dies 110 and 111 have metallization on the top or second sides, and the first portion 131 of the first plate 130 is soldered to the top sides of the semiconductor dies 110 and 111. In another implementation, the first portion 131 of the first plate 130 is attached to the second sides of the semiconductor dies 110 and 111 by an adhesive (not shown). The adhesive in this example is thermally conductive, and may be electrically conductive, although electrical conductivity of such adhesive is not a requirement of all possible implementations.

The example first plate 130 includes a second portion 132 and a third portion 133 that extend from respective opposite ends of the first portion 131 to form an upwardly positioned contiguous U-shaped metal structure, where the third portion 133 is laterally spaced apart from the second portion 132 along the first direction X. In another implementation, one of the portions 132, 133 can be omitted. In further implementations, one or both of the second portion 132 and/or the third portion 133 can extend from a different location of the first portion 131, and the portions 132 and 133 need not be at the ends of the first portion 131. In the illustrated example, the second and third portions 132 and 133 extend upwardly from the first portion 131 away from the semiconductor die 110 along the third direction Z as best shown in FIGS. 1 and 1D. The second portion 132, and the third portion 133 (if included) provide a thermally conductive path to extract heat from the top sides of the semiconductor dies 110 and 111 toward the top side 102 of the electronic device 100. The first plate 130 in one example is or includes a conductive metal, such as copper, aluminum, etc. In other implementations, the first plate 130 can be any suitable thermally conductive material. The U-shaped metal example first plate 130 provides a low-cost easily manufactured component to promote internal heat extraction from the semiconductor dies 110 and 111 while accommodating the overlying positioning of the first portions 141 of the metal clips 140. This provides thermal performance benefits without increasing the package size for integrated magnetics.

As further shown in FIGS. 1 and 1D, the second plate 150 is partially exposed outside the top side 102 of the package structure 108 and is thermally coupled to the second and third portions 132 and 133 of the first plate 130. In the illustrated example, the package structure 108 includes first and second recesses 109 that extend into the top or second side 102 of the package structure 108 along the third direction Z (FIGS. 1 and 1A). The second plate 150 in one example is or includes a conductive metal, such as copper, aluminum, etc. In other implementations, the second plate 150 can be any suitable thermally conductive material. The example second plate 150 is a U-shaped contiguous metal structure with opposite ends that are spaced apart from one another along the first direction X and are thermally coupled to respective ends of the second and third portions 132 and 133 of the first plate 130.

The illustrated example provides solder connection of metal plates 130 and 150 in the recesses 109 of the package structure 108 as shown in FIGS. 1, 1A and 1D. This example includes solder 154 that couples the second plate 150 to the second portion 132 and 133 of the first plate 130 in the recess 109 that extends into the top or second side 102 of the package structure 108. The second plate 150 includes a first portion 151 with a top side (e.g., FIGS. 1 and 1D) that is exposed outside the package structure 108 and a bottom side that extends in one example along the top side 102 of a portion of the package structure 108 The second plate 150 also includes a second portion 152 that extends downward from a first end of the first portion 151 along the third direction Z into solder 154 in the first recess 109, as well as a third portion 153 that extends downward from an opposite second end of the first portion 151 into the solder 154 of the second recess 109.

The solder connection of the first and second plates 130 and 150 provides a highly thermally conductive path between the semiconductor dies 110 and 111 and the exterior of the electronic device 100. The second portion 132 of the first plate 130 is thermally coupled to the second portion 152 of the second plate 150 by the solder 154, where the second portions 132 and 152 can engage one another in some implementations or can be physically spaced apart from one another with thermally conductive material therebetween (e.g., solder 154). The third portion 133 of the first plate 130 is thermally coupled to the third portion 153 of the second in the second recess 109 plate 150 by the solder 154, where the third portions 133 and 153 can engage one another in some implementations or can be physically spaced apart from one another with thermally conductive material therebetween (e.g., solder 154).

In another example, a different form of thermal coupling can be used, such as thermally conductive adhesive in the recesses 109 of the package structure 108 that thermally couples the second portions 132 and 152 of the respective first and second plates 130 and 150, and also thermally couples the third portions 133 and 153 of the plates 130 and 150, respectively. In one implementation, such a thermally conductive adhesive can also be electrically conductive. For example, it may be beneficial to expose a ground or other reference voltage (e.g., of the top or back sides of the semiconductor dies 110, 111) outside the package structure 108 along the top side 102 of the electronic device, and a conductive metal heat sink (not shown) can be attached to the top side of the first portion 151 along the top of the electronic device 100 for better heat removal. In another implementation, a thermally conductive, electrically insulating (e.g., nonconductive) adhesive can be used to couple the first and second plates 130 and 150. This example may be beneficial where both plates 130, 150 have respective second and third portions that create a structure that encircles the first portions 141 of the metal clips 140 (e.g., FIG. 1), and it is not desired to have a continuous electrically conductive structure that encircles the metal clips 140.

In another example, a flat top second plate can be used (e.g., having no second or third portions 152 or 153), with solder and/or adhesive connection to the end of the second portion 132 (and that of any included third portion 133) of the first plate 130, either with or without a corresponding recess 109 and the package structure 108. However, the provision of the recesses 109 extending into the top side 102 of the package structure 108 advantageously allows selective exposure of the top sides of the second and third portions 132 and 133 of the first plate 130 by material removal processing after molding. In this example, the dimensions of the mold (e.g., along the third direction Z) and the dimensional tolerance variations in the vertical heights of the components (e.g., the semiconductor dies 110 and 111, the first metal plate 130, etc.) is less critical and precise molding control is not required, while still allowing thermal coupling of the first and second plates 130 and 150 to create a thermal extraction structure within the packaged electronic device 100 while accommodating integrated magnetic components by use of the metal clips 140 and magnetic molding compound material of the package structure 108.

As further shown in FIG. 1, the substrate 107 includes conductive leads 125, 126 that are configured to be electrically coupled to a circuit board 160, for example, by solder connections as shown or by insertion into a corresponding socket (not shown). The electronic device 100 can be installed in any suitable form of system, for example, for power conversion, communications, isolation, etc. The system example of FIG. 1 includes a circuit board 160 with conductive traces 162 along a top side. The leads 126 and the interior isolated split pads 128 along the first side 101 of the electronic device 100 are soldered to respective ones of the circuit board conductive traces 162. In another example, the electronic device 100 can be installed in a socket (not shown) of the circuit board 160 with the conductive leads 126 and the split pads 128 engaging corresponding conductive metal features of the socket to form electrical connections between the electronic device 100 and the circuit board 160.

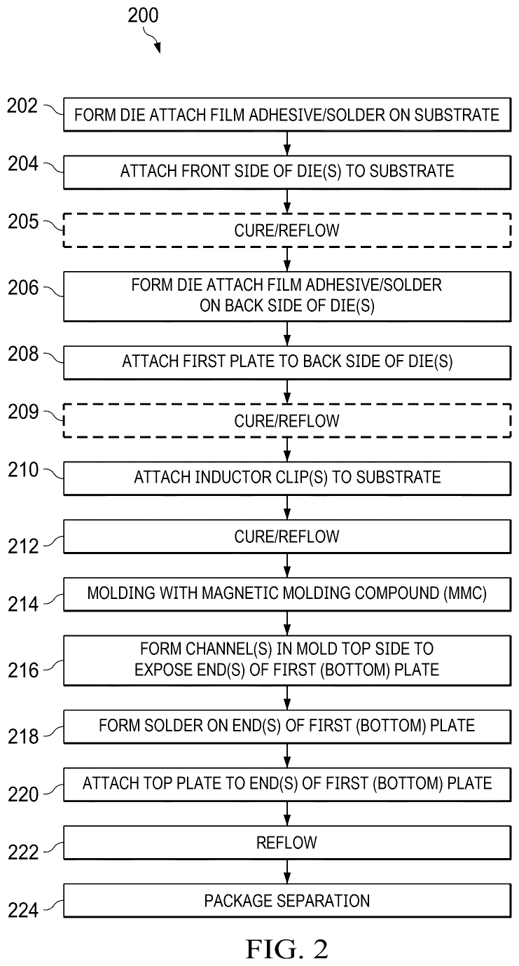

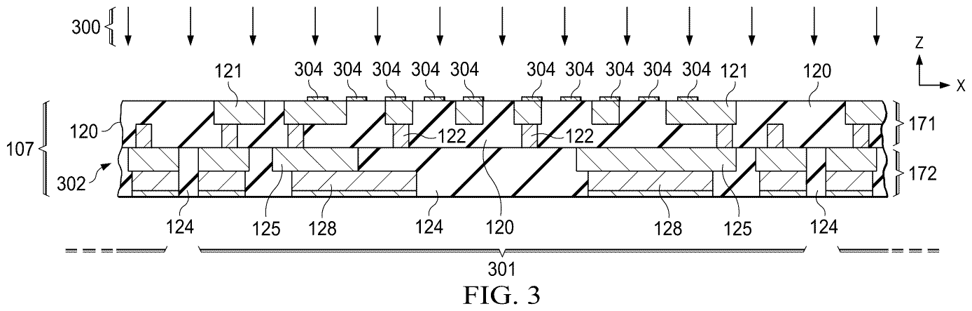

Referring now to FIGS. 2-16, FIG. 2 shows a method 200 of fabricating an electronic device and FIGS. 3-16 illustrate one example of the above described electronic device 100 undergoing fabrication processing according to one implementation of the method 200. The illustrated example begins with a starting substrate panel array 302 as shown in FIG. 3, fabricated to include instances of the first and second levels 171 and 172 (and any desired intermediate levels, not shown) as described above, and the panel array structure includes rows and columns of unit areas 301 corresponding to the multilevel package substrate 107 of a subsequently separated electronic device 100. The illustrated implementation of the method 200 uses conductive metal solder for attachment of various components, with one or more solder reflow operations to create solder joints. In other implementations, one or more components can be alternatively attached using conductive or nonconductive adhesive, and such implementations can include adhesive curing processes, such as thermal curing, ultraviolet (UV) curing, etc.

The method 200 includes die attachment processing at 202-205 in FIG. 2 to attach the instances of the first and second semiconductor dies 110 and 111 and any other surface mount passive or active components (not shown) of a given design in each unit area 301 of the substrate panel array structure 302. FIGS. 3-5 illustrate one example, in which the semiconductor dies 110 and 111 are flip chip soldered to corresponding conductive features 121 on the top side of the substrate panel array 302 in the illustrated unit area 301. At 202 in FIG. 2, solder paste 304 is formed on select portions of the top side of the prospective substrate in each unit area 301 of the substrate panel array 302. In another example, a conductive die attach adhesive film (not shown) is formed on select portions of the top side of the prospective substrate in each unit area 301.

FIG. 3 shows one example, in which a solder paste formation process 300 is performed that forms solder paste 304 over designated portions of the top side of the substrate panel array 302 in the illustrated unit area 301 to which a component or a terminal of a component is to be attached. Any suitable solder paste formation process 300 and equipment can be used, for example, dispensing, printing, silk screening, etc. In one example, the solder paste formation process 300 forms solder paste 304 over prospective connection areas corresponding to the first and second semiconductor dies 110 and 111, as well as prospective connection areas corresponding to the outwardly extending landing pads or feet at each end of the metal clips 140. In another implementation, the solder paste formation for the landing pads of the metal clips 140 can be performed later.

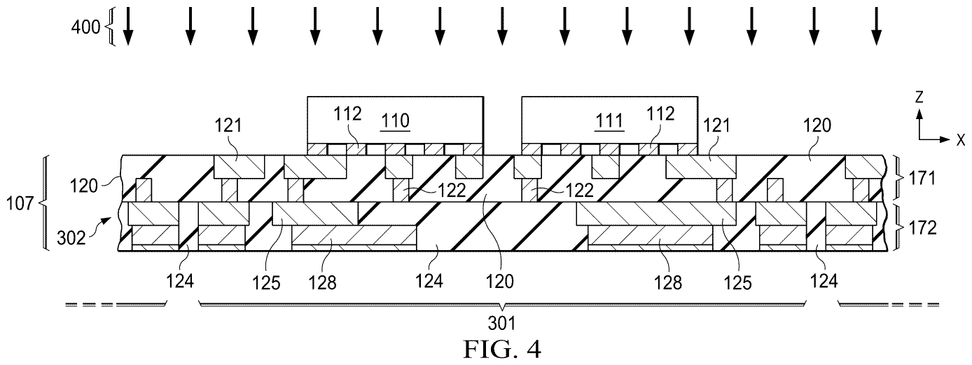

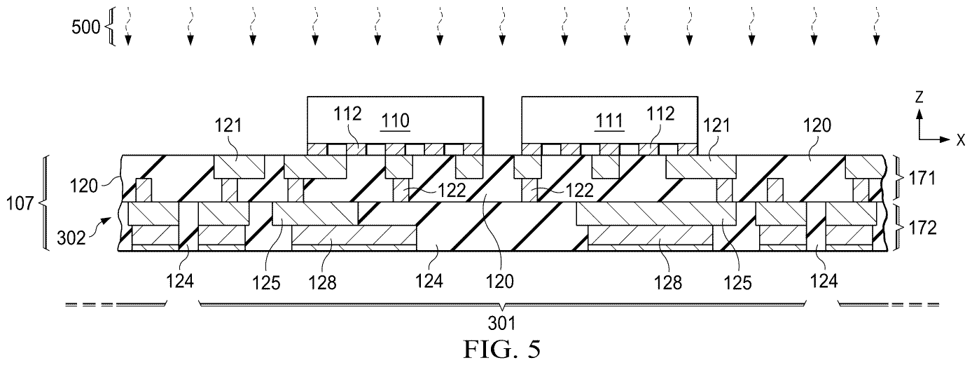

At 204 in FIG. 2, the semiconductor dies 110 and 111 (and potentially other surface mount components, not shown) are placed in appropriate locations, for example, using automated pick and place equipment (not shown). FIG. 4 shows one example, in which a component placement or die attach process 400 is performed that positions the semiconductor dies 110 and 111 on the top side of the substrate panel array 402 in the illustrated unit area 301. The die attach process 400 in this example engages conductive metal terminals of the components and the terminals 112 of the semiconductor dies 110 and 111 to the previously formed solder paste 304 in each unit area 301.

In one example, the method 200 includes an initial solder paste reflow (or die attach film curing) operation at 205 in FIG. 2. In another implementation, the curing or reflow processing at 205 can be omitted, and the solder paste 304 can be cured later in the process, for example, after attachment of the first plate 130 and/or the metal clips 140. FIG. 5 shows one example, in which a solder reflow process 500 is performed, such as a thermal reflow process to create solder joints between the terminals of the semiconductor dies 110 and 111 and the corresponding trace features 121 of the multilevel package substrate 107.

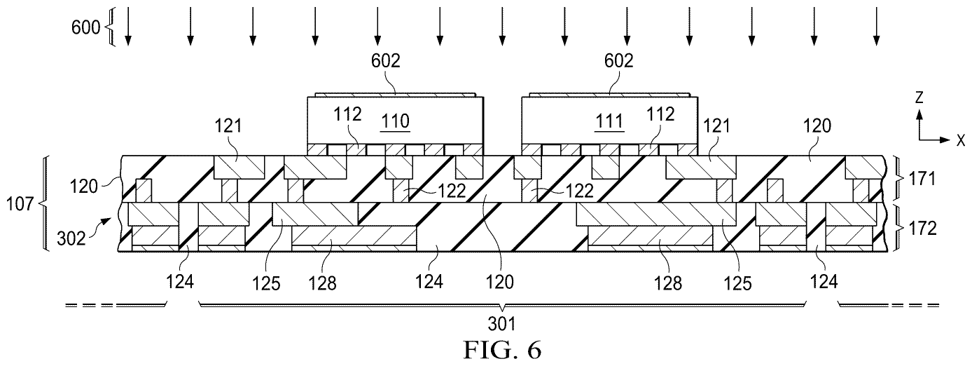

The method 200 continues with plate attachment processing at 206-209 in FIG. 2 to attach the instances of the first plate 130 to the top sides of the semiconductor dies 110 and 111 in each unit area 301 of the substrate panel array structure 302. In one example, further solder paste (or die attach film adhesive) is formed at 206 in FIG. 2 along the upper or back sides of the semiconductor dies 110 and 111. In another example, the solder paste formation at 206 can also form solder in the prospective areas of the top of the substrate 107 to which the metal clips 140 are to be attached. FIG. 6 shows one example, in which another solder paste formation process 600 is performed that forms solder paste 602 over designated portions of the top sides of the semiconductor dies 110 and 111 in the illustrated unit area 301 to which the first portion 131 of the first plate 130 is to be attached. Any suitable solder paste formation process 600 and equipment can be used, for example, dispensing, printing, silk screening, etc.

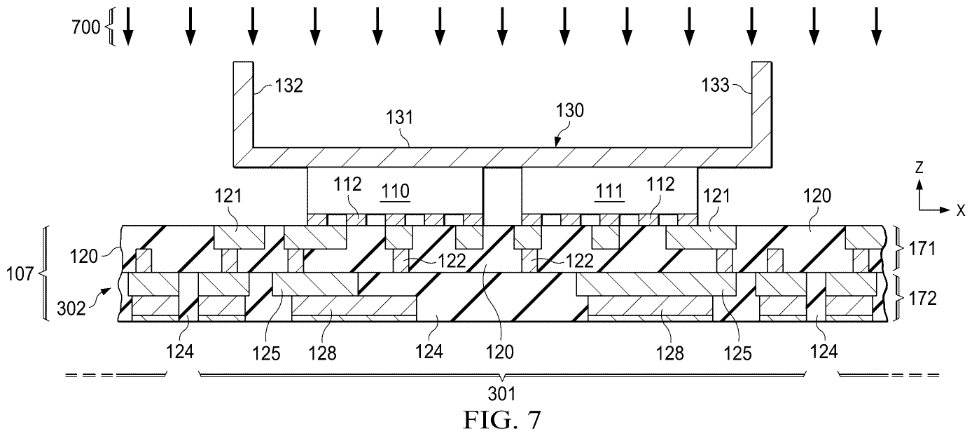

The method 200 in this example continues at 208 in FIG. 2 with first plate attachment to appropriate locations on the top sides of the semiconductor dies 110 and 111, for example, using automated pick and place equipment (not shown). FIG. 7 shows one example, in which a plate placement or attach process 700 is performed that positions the first portion 131 of the first plate 130 on the top sides of the semiconductor dies 110 and 111 in the illustrated unit area 301. The plate attach process 700 in this example engages conductive metal of the first portion 131 of the first plate 130 to the previously formed solder paste 302 in each unit area 301 of the substrate panel array 302.

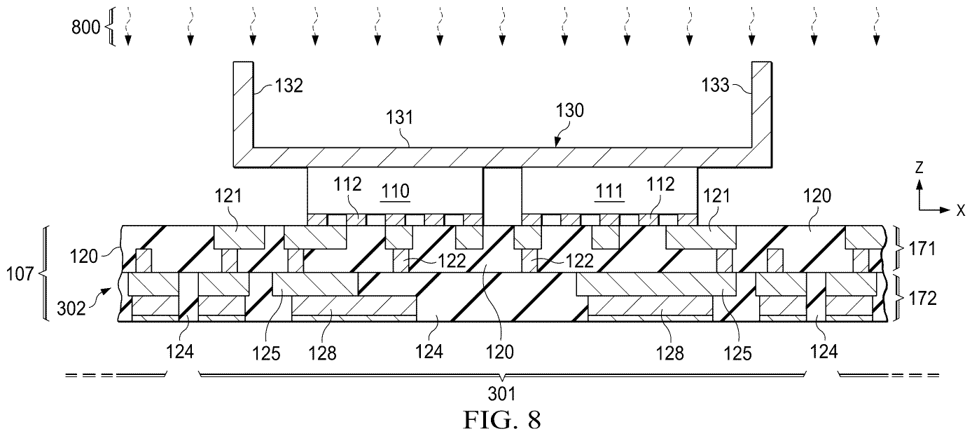

In one example, the method 200 includes a second or further solder paste reflow (or die attach film curing) operation at 209 in FIG. 2. In another implementation, the curing or reflow processing at 209 can be omitted, and the solder paste 602 can be reflowed (or an adhesive can be cured) later in the process, for example, after attachment of the first plate 130 and/or the metal clips 140. FIG. 8 shows one example, in which a solder reflow process 800 is performed, such as a thermal reflow process to create solder joints between the backside metal along the top sides of the semiconductor dies 110 and 111 and at least a portion of the bottom side of the first portion 131 of the first plate 130. The processing at 206-209 attaches an instance of the first plate 130 with second and third portions 132 and 133 extending upward along the third direction from the first portion 131 away from the semiconductor dies 110 and 111 in each unit area 301.

The method 200 continues at 210 and 212 in FIG. 2 with metal clip attachment processing to attach the instances of the metal clips 140 to corresponding conductive features 121 of the top side of the substrate 107 in each unit area 301 of the substrate panel array structure 302. In one example, further solder paste (or die attach film adhesive) can be formed at 210 in FIG. 2 along the conductive features 121 to which the metal clips 140 are to be attached (e.g., dispensing, printing, silk screening, etc.). In another example, the solder paste for attachment of the metal clips 140 has been previously formed on the corresponding conductive features 210 at an earlier point in the method 200, such as at 202-4206 in FIG. 2.

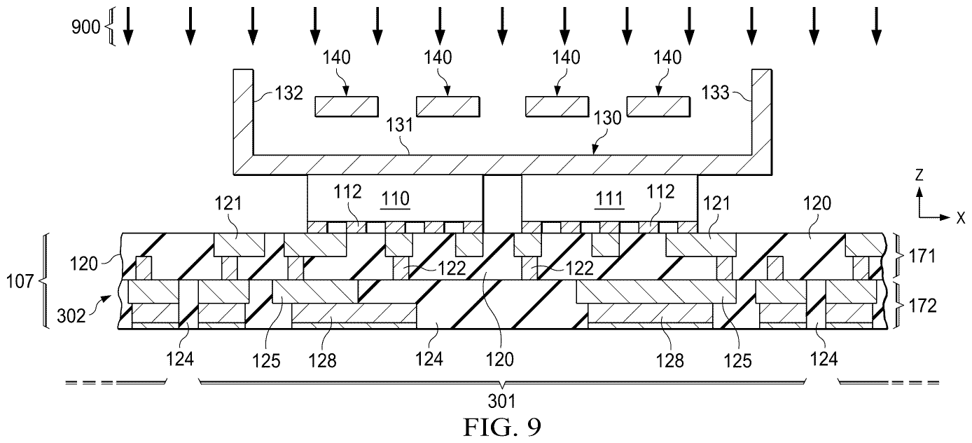

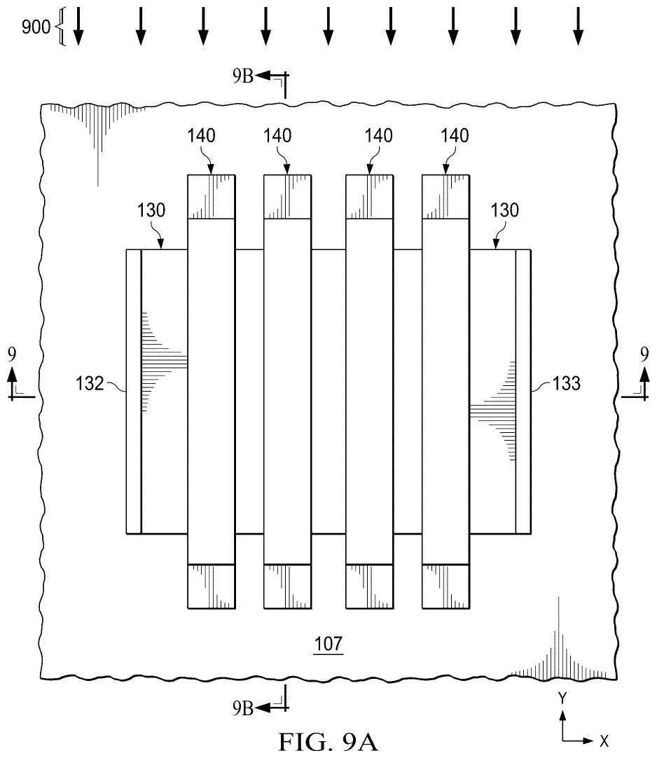

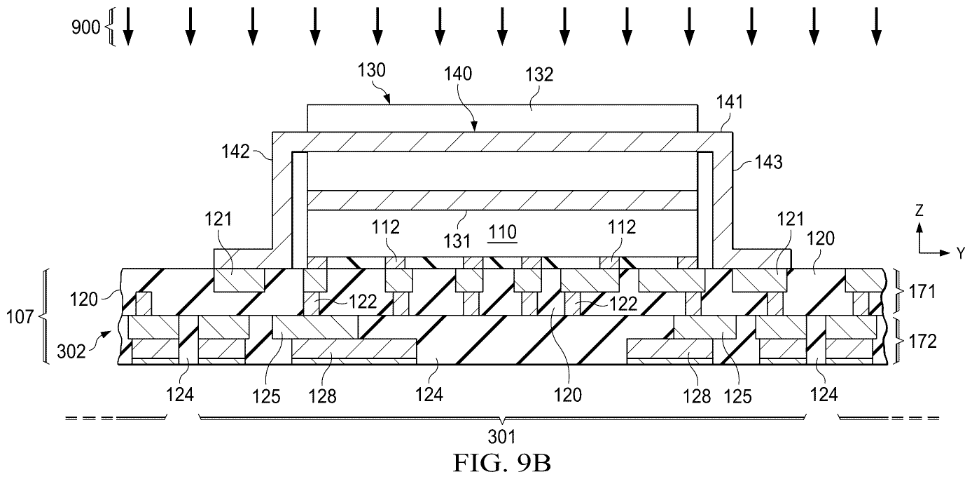

The method 200 in this example continues at 210 in FIG. 2 with metal clip attachment to appropriate locations on the top side of the substrate 107, for example, using automated pick and place equipment (not shown). FIGS. 9, 9A and 9B show respective side section, top and end section views of one example, in which a plate placement or attach process 900 is performed that attaches the respective second and third clip portions 142 and 143 of a metal clip 140 to respective conductive features 121 of the substrate 107 using previously formed solder paste (not shown) with the first clip portion 141 of the metal clip 140 above and spaced apart from the first portion 131 of the first plate 130 along the third direction Z. The attached first clip portion 141 extends between the second and third clip portions 142 and 143 (e.g., as illustrated and described above in connection with FIGS. 1 and 1B-1E). The process 900 in this example attaches the desired number of the metal clips 140 at respective locations in each unit area 301 of the substrate panel array 302.

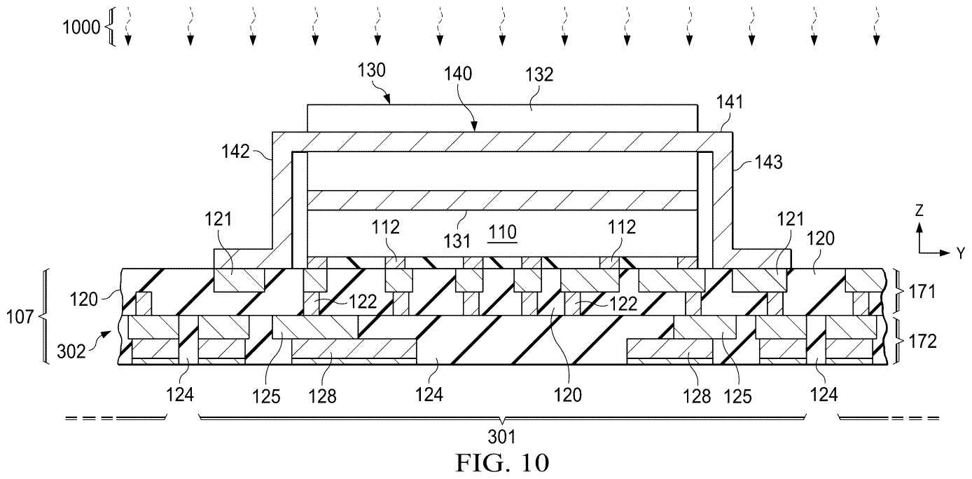

The method 200 in this example includes a final solder paste reflow (or die attach film curing) operation at 212 in FIG. 2. FIG. 10 shows one example, in which a solder reflow process 1000 is performed, such as a thermal reflow process to create solder joints between the outwardly extending landing pads or feet at each end of the respective metal clips 140 and the corresponding conductive features 121 of the substrate 107. This process 1000 create a solder connection of the second clip portion 142 of a first metal clip 140 to a first conductive feature 121 of the substrate 107, a solder connection of the third clip portion 143 of the first metal clip 140 to a second conductive feature 121 of the substrate 107, a solder connection of the second clip portion 142 of a second metal clip 140 to a third conductive feature 121 of the substrate 107, a solder connection of the third clip portion 143 of the second metal clip 140 to a fourth conductive feature 121 of the substrate 107, and so on for any further metal clips (e.g., four metal clips 140 in the illustrated example) in each unit area 301 of the substrate panel array 302.

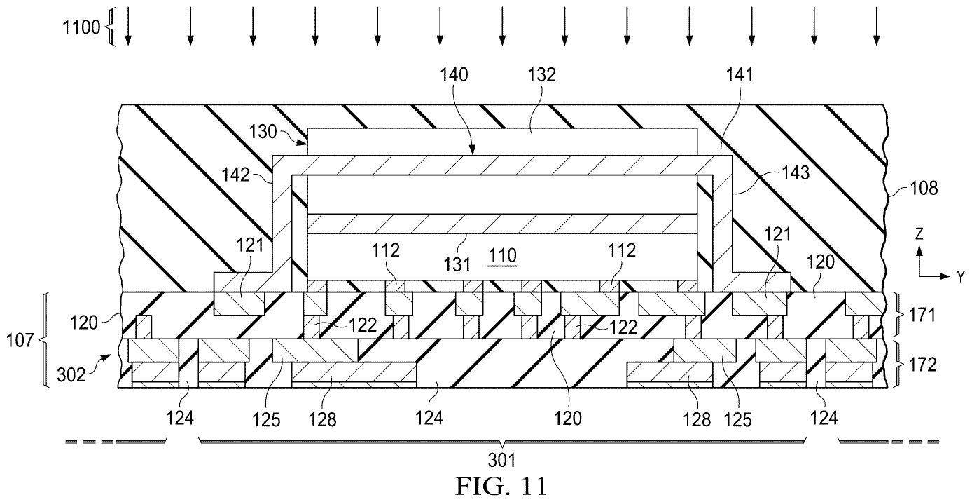

The method 200 continues at 214 in FIG. 2 with molding processing to form the molded package structure 108 that includes magnetic molding compound that encloses the metal clips 140, the semiconductor dies 110, 111 and the first portion 131 of the first plate 130 in the magnetic molding compound in each unit area 301 of the substrate panel array 302. FIG. 11 shows one example, in which a molding process 1100 is performed to form the molded package structure 108 that extends above the metal clips 140 and above the upwardly extending second and third portions 132 and 133 of the first plate 130. In one example, the molding process 1100 incorporates a magnetic material in the package structure 108, for example, using magnetic mold compound.

In one example, a single mold cavity can be used to form a unitary magnetic molded structure 108 that extends across all the rows and columns of the panel array structure. In another implementation, individual mold cavities can be used to form respective molded magnetic package structures 108 in each unit area 301. In other implementations, the individual mold cavities can extend across two or more unit areas 301 of the array structure, for example, to form magnetic molded package structures 108 along rows or columns of the array structure. The method 200 in one example can include optional plating (not shown) of the leads and split pads in each unit area 301 of the panel array after molding at 214.

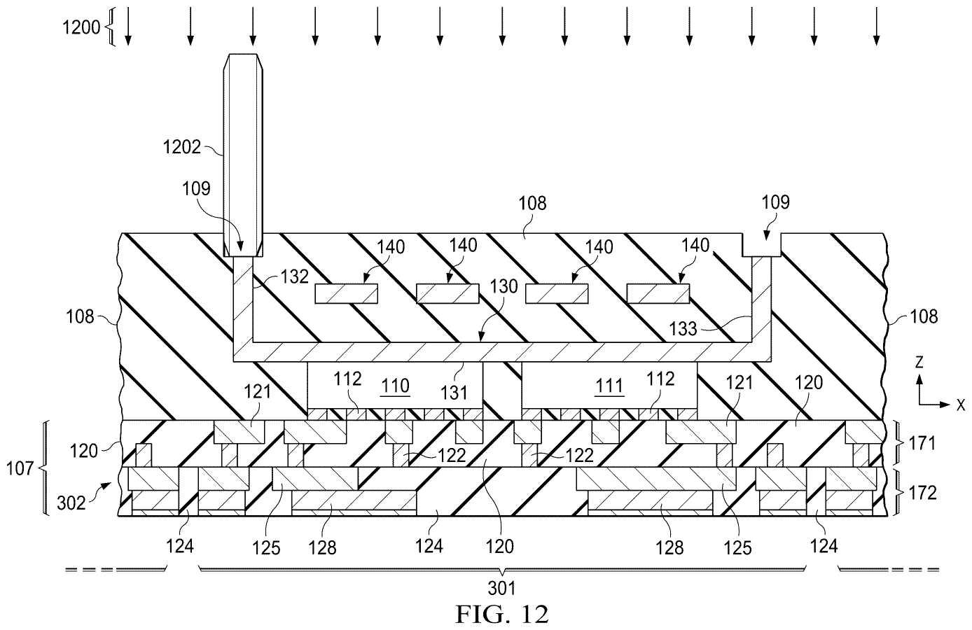

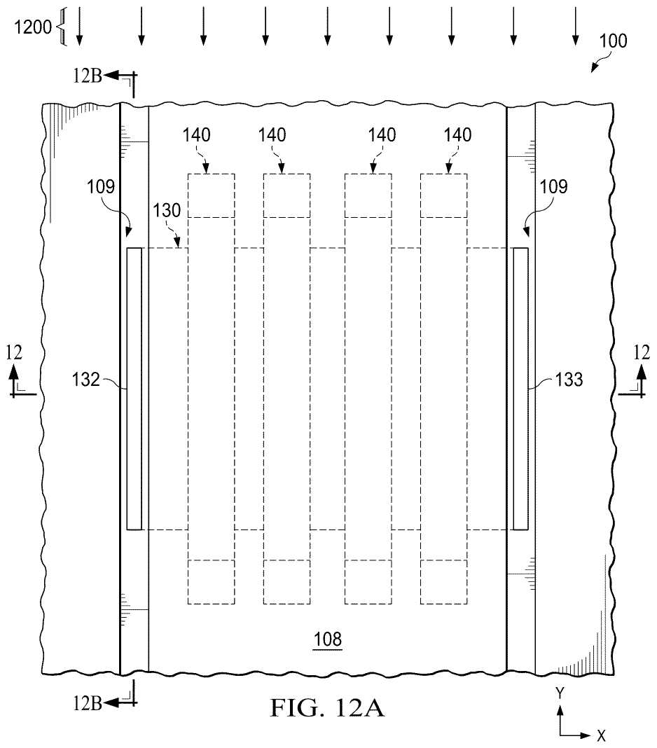

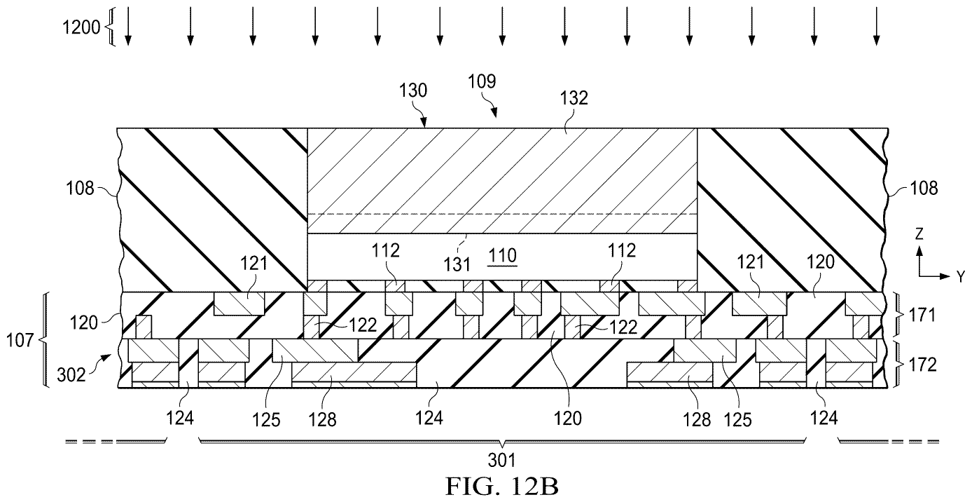

The method 200 continues at 216 in FIG. 2 with selectively removing a portion of the over molded package structure 108 to expose the top ends of the second and third portions 132 and 133 of the first plate 130 to form the recesses 109 (e.g., channels) that extend downward into the top side 102 of the molded package structure 108. Any suitable material removal process can be used, such as partial cutting using a package separation tool (e.g., cutting blade), laser material removal (e.g., ablation), etc. FIGS. 12, 12A and 12B show respective side section, top, and end section views of one example, in which a cutting process 1200 is performed using a raised package separation cutting blade 1202 (FIG. 12) that forms the recesses 109 that individually extend into the top side 102 of the molded package structure 108 and exposes the ends of the second and third portions 132 and 133 of the first plate 130.

In another example, the selective material removal processing at 216 can include performing a laser ablation process (not shown) to form the recesses 109 that extend into the side 102 of the package structure 108 and expose the ends of the second and third portions 132 and 133 of the first plate 130. The cutting process 1200 may in some implementations remove a small portion of the top ends of the second and third portions 132 and 133 of the first plate 130 in one or more unit areas 301, although not a requirement of all possible implementations. The process 1200 removes enough of the molded package structure material 1082 expose the second and third portions 132 and 133 of the first plate 130 or to otherwise allow thermal coupling of the second and third portions 132 and 133 of the first plate 130 to an attached second plate 150 to provide thermal performance enhancement of the ultimately separated electronic devices.

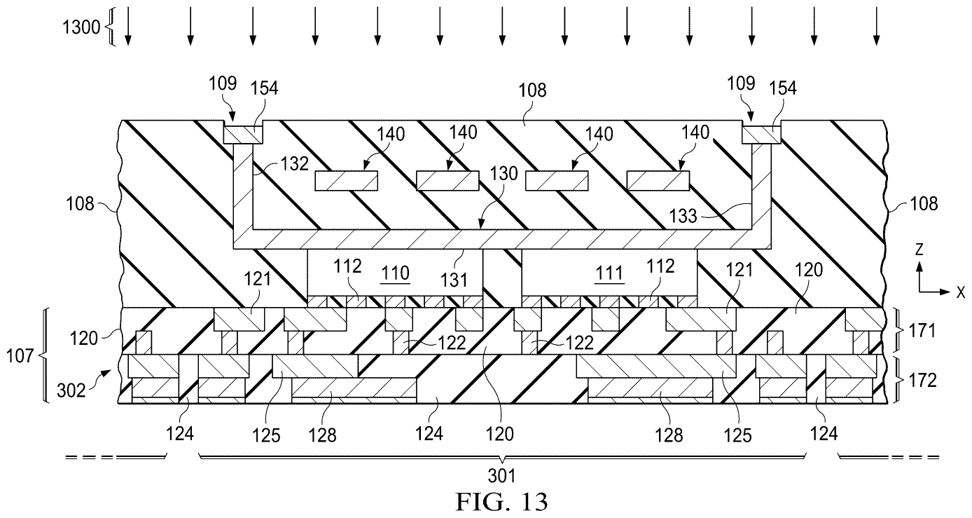

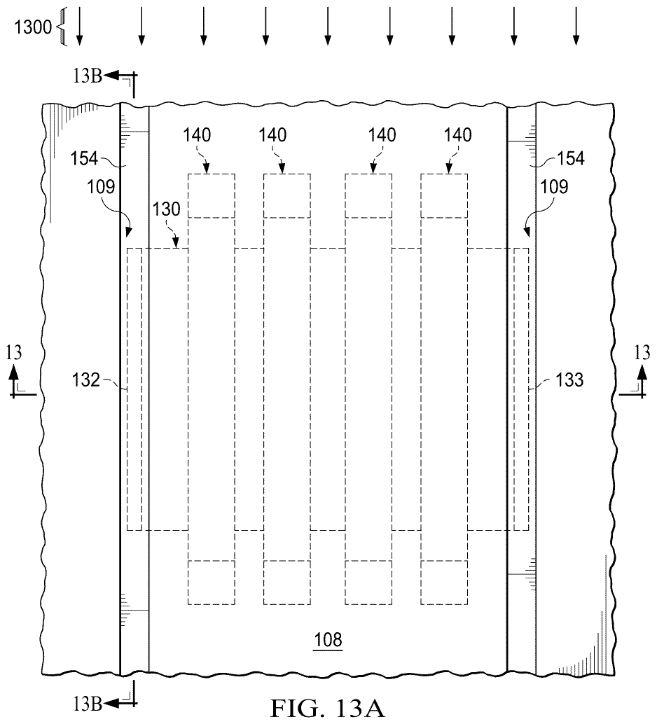

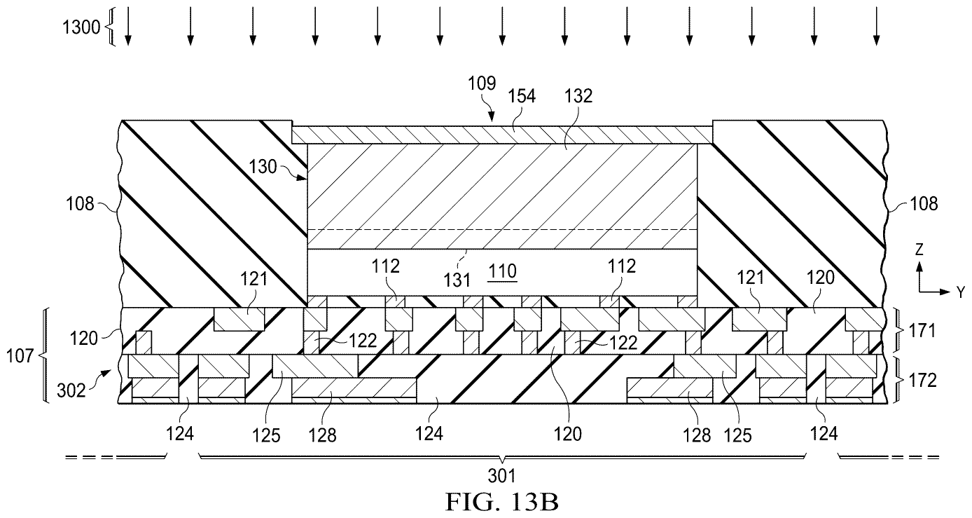

The method 200 also includes thermally coupling the second plate 150 to exposed surface of the second and third portions 132 and 133 of the first play 130, leaving a top side portion of the second plate 150 at least partially exposed outside the package structure 108. In one example, the thermal coupling includes forming a solder connection between the first and second plates 130 and 150 at 218-222 in FIG. 2. The illustrated example includes forming solder at 218 in FIG. 2. FIGS. 13, 13A and 13B show respective side section, top and end section views of one example, in which a solder formation process 1300 is performed that forms the solder 154 on the upwardly facing ends of the second and third portions 132 and 133 of the first plate 130 in the previously formed recesses 109 of the package structure 108. The solder formation process 13 can be any suitable solder deposition or formation process, such as dispensing, printing, silk screening, etc.

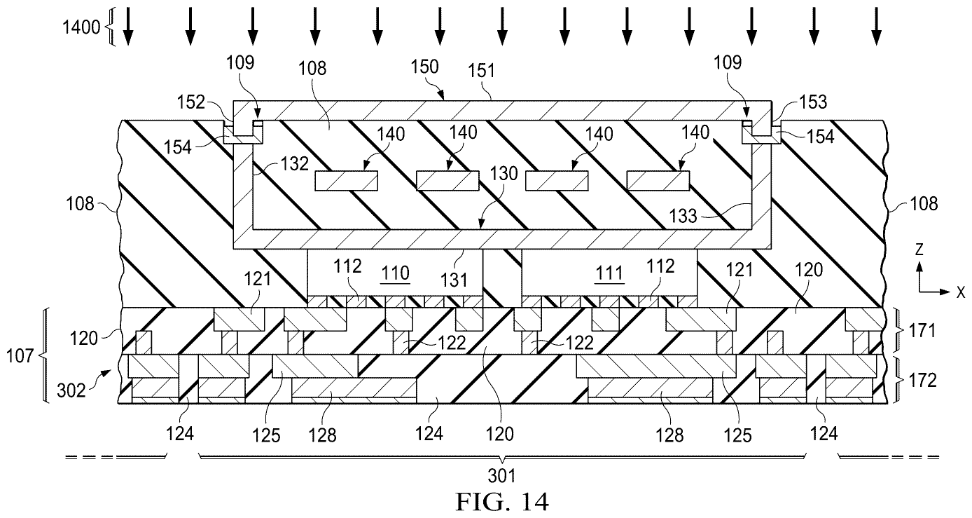

This example implementation continues at 220 in FIG. 2 with attaching the second plate 150 to the package structure 108. FIG. 14 shows one example, in which a plate attachment process 1400 is performed that attaches the first portion 151 of the second plate 150 to the package structure 108. In other implementations, the first portion 151 of the second plate 150 need not contact the top side 102 of the package structure 108. In the illustrated example, the attachment process 1400 engages the second and third portions 152 and 153 of the second plate 150 with solder 154 in the respective recesses 109 in each unit area 301 of the substrate panel array structure 302. The downwardly extending bottom face or end of the second portion 152 of the second plate 150 can, but need not, engage the upwardly extending face or end of the second portion 132 of the first plate 130. Similarly, the downwardly extending bottom face or end of the third portion 153 of the second plate 150 can, but need not, engage the upwardly extending face or end of the third portion 133 of the first plate 130.

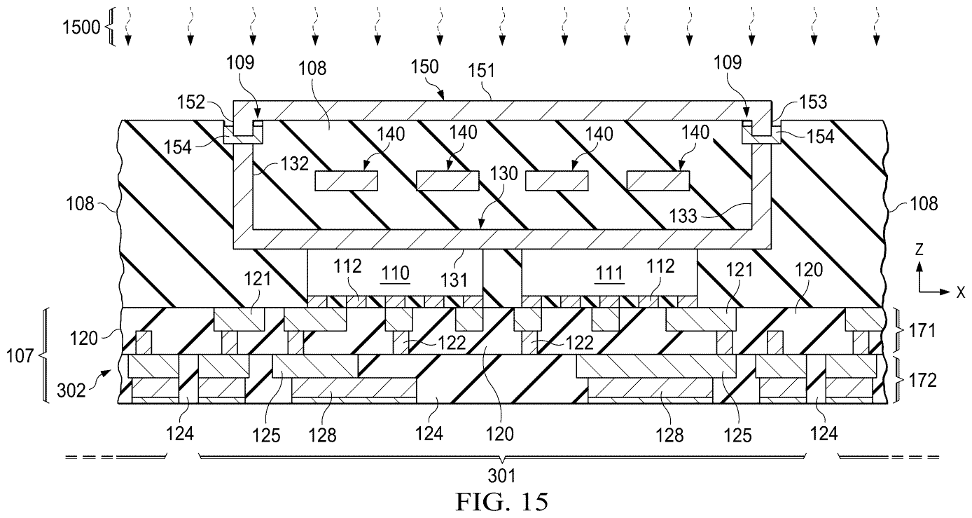

At 222 in FIG. 2, the method 200 further includes reflowing the solder 154 in the recesses 109 of the package structure 108. FIG. 15 shows one example, in which a thermal reflow process 1500 is performed that reflows the solder paste 154 in the recesses 109 of the package structure 108 and forms solder connections between the first and second plates 130 and 150. The process 1500 forms a first solder connection between the second portion 152 of the second plate 150 and the second portion 132 of the first plate 130, and a second solder connection between the third portion 153 of the second plate 150 and the third portion 133 of the first plate 130. As previously discussed, other implementations of the first plate 130 may only have one upwardly extending portion (e.g., the second portion 132), in which case a corresponding single recess 109 can be formed at 216 and a single solder connection can be formed at 218-222 in FIG. 2 to provide thermal coupling of the first plate 130 to the attached second plate 150. In other implementations, for example, having more than two upwardly extending portions of the first plate 130, a corresponding number of recesses 109 can be formed in the package structure 108 and a corresponding number of thermal couplings (e.g., solder connections, thermally conductive adhesive connections, etc.) can be made to thermally couple the first and second plates 130 and 150.

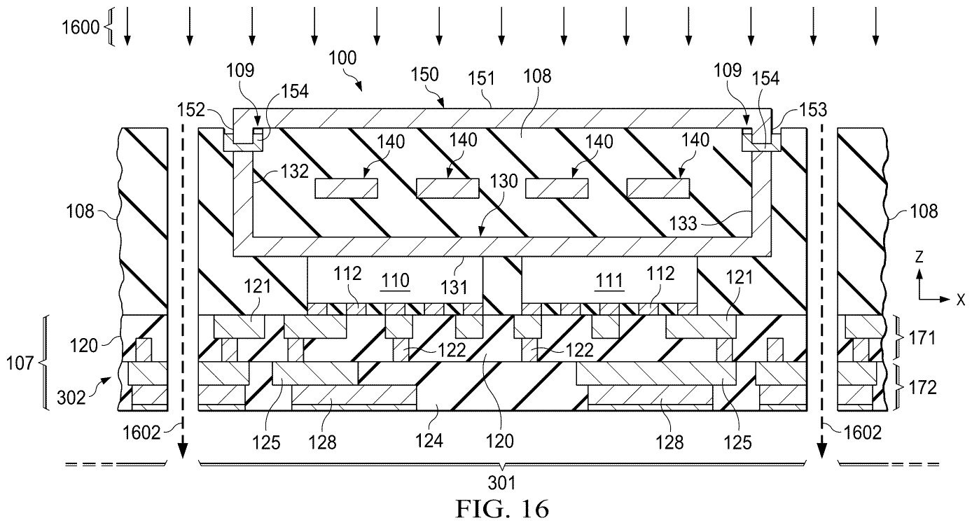

The method 200 in one example continues at 224 in FIG. 2 with package separation. FIG. 16 shows one example, in which a saw cutting or laser cutting process 1600 is performed that separates individual finished packaged electronic devices 100 from the concurrently processed panel or array structure 302 along lines 1302. Any suitable package separation process 1600 can be used, for example, saw cutting, laser cutting, chemical etching, etc., or combinations thereof. In one example, the same or a similar package separation tool or equipment can be used to initially form the recess or recesses 109 in the package structure 108 (e.g., at 216 in FIG. 2), with the example cutting tool adjusted to raise the cutting blade 1202 (FIG. 12) for the formation of the recesses 109. Thereafter, the blade height can be adjusted and controlled in the package separation process 1600 (FIG. 16) to separate the finished electronic devices 100 from the panel array structure 302.

Described examples advantageously combine the use of magnetic molding compound with integrated magnetic component structures (e.g., metal clips 140) to form on-board inductors, transformers windings, etc. in a compact packaged electronic device 100, along with thermally conductive heat removal structures formed by the first and second plates 130 and 150. The illustrated example provides a thermally conductive heat removal path from the top sides of the semiconductor dies 110 and 111 to the top side 102 of the package structure. The described examples facilitate intrinsic heat removal that can optionally be enhanced by attachment of an external heat sink (not shown) to the top side of the second plate 150.

The described examples further provide compact integrated magnetic structures with the metal clips 140 combined with conductive routing structures of the substrate 107 providing one or more inductor or transformer winding turns in a compact format. The illustrated examples, moreover, facilitate cost effective manufacturing that allows use of existing molds with cavities that do not need to be modified to accommodate the final dimensional tolerances along the third direction Z, with the selective material removal (e.g., at 216 in FIG. 2) advantageously accommodating any final molded package structure height and dimensional stack variations in the final position of the upwardly extending portions 132 and 133 of the first plate 130.

The described solution employs magnetic mold compound that is over molded (e.g., thinnest at approximately 100 um) and can use partial singulation to create the recesses 1094 introducing solder 154 to attach the top or second plate 150 and form thermal connections to the lower or first plate 130. Certain implementations can maintain a pre-existing mold chase design which may be limited to a certain thickness and use a known singulation method to expose areas on the package for thermally coupling the plates 130 and 150. Certain examples, moreover, avoid the added cost of grinding to expose the first plate landing portions 132 and 132 and the cost and challenges associated with designing a specific mold chase to maintain package height.

Modifications are possible in the described examples, and other implementations are possible, within the scope of the claims.

What is claimed is:

1. An electronic device, comprising:
a semiconductor die having opposite first and second sides, the first side attached to a substrate;
a first plate having first and second portions, the first portion attached to the second side of the semiconductor die and the second portion extending from the first portion away from the semiconductor die;
a metal clip having a first clip portion, a second clip portion, and a third clip portion, the second clip portion coupled to a first conductive feature of the substrate, the third clip portion coupled to a second conductive feature of the substrate, the first clip portion above and spaced apart from the first portion of the first plate and extending between the second and third clip portions;
a package structure including magnetic molding compound that encloses the metal clip, the semiconductor die, and the first portion of the first plate; and
a second plate at least partially exposed outside the package structure and thermally coupled to the second portion of the first plate.

2. The electronic device of claim 1, further comprising solder that couples the second plate to the second portion of the first plate.

3. The electronic device of claim 2, wherein the second plate is coupled to the second portion of the first plate in a recess that extends into a side of the package structure.

4. The electronic device of claim 1, wherein the first and second plates are metal.

5. The electronic device of claim 1, wherein the metal clip forms a portion of a turn of an inductor or transformer.

6. The electronic device of claim 5, wherein the metal clip is a first metal clip, the electronic device further comprising a second metal clip spaced apart from the first metal clip and enclosed by the package structure, the second metal clip having a first clip portion, a second clip portion, and a third clip portion, the second clip portion of the second metal clip coupled to a third conductive feature of the substrate, the third clip portion of the second metal clip coupled to a fourth conductive feature of the substrate, the first clip portion of the second metal clip above and spaced apart from the first portion of the first plate and extending between the second and third clip portions of the second metal clip.

7. The electronic device of claim 1, wherein the substrate includes conductive leads configured to be soldered to a circuit board.

8. The electronic device of claim 1, wherein:
the first plate has a third portion spaced apart from the second portion and extending from the first portion away from the semiconductor die; and
the second plate is thermally coupled to the third portion of the first plate.

9. The electronic device of claim 1, wherein the first portion of the first plate is electrically coupled to the second side of the semiconductor die.

10. The electronic device of claim 1, wherein:
the semiconductor die is a first semiconductor die;
the electronic device further comprising a second semiconductor die having opposite first and second sides, the first side of the second semiconductor die attached to the substrate; and
the first portion of the first plate is attached to the second side of the second semiconductor die.

11. A system, comprising:
a circuit board having a conductive trace; and
an electronic device, comprising:
a substrate having opposite first and second sides, a lead along the first side of the substrate, and first and second conductive features along the second side of the substrate, the lead electrically coupled to the conductive trace of the circuit board;
a semiconductor die having opposite first and second sides, the first side attached to the second side of the substrate;
a first plate having first and second portions, the first portion attached to the second side of the semiconductor die and the second portion extending from the first portion away from the semiconductor die;
a metal clip having a first clip portion, a second clip portion, and a third clip portion, the second clip portion coupled to a first conductive feature of the substrate, the third clip portion coupled to a second conductive feature of the substrate, the first clip portion above and spaced apart from the first portion of the first plate and extending between the second and third clip portions;
a package structure including magnetic molding compound that encloses the metal clip, the semiconductor die, and the first portion of the first plate; and
a second plate at least partially exposed outside the package structure and thermally coupled to the second portion of the first plate.

12. A method of fabricating an electronic device, the method comprising:
attaching a first side of a semiconductor die to a substrate;
attaching a first portion of a first plate to an opposite second side of the semiconductor die with a second portion of the first plate extending from the first portion away from the semiconductor die;
attaching second and third clip portions of a metal clip to respective conductive features of the substrate with a first clip portion of the metal clip above and spaced apart from the first portion of the first plate and the first clip portion extending between the second and third clip portions;
forming a package structure including magnetic molding compound that encloses the metal clip, the semiconductor die, and the first portion of the first plate;
removing a portion of the package structure to expose the second portion of the first plate; and
thermally coupling a second plate to an exposed surface of the second portion of the first plate with a portion of the second plate at least partially exposed outside the package structure.

13. The method of claim 12, wherein attaching the semiconductor die to the substrate includes flip chip soldering conductive terminals of the semiconductor die to conductive features of the substrate.

14. The method of claim 12, wherein:
the semiconductor die is a first semiconductor die;
the method further comprises attaching a first side of a second semiconductor die to the substrate; and
attaching the first portion of the first plate to an opposite second side of the second semiconductor die.

15. The method of claim 12, wherein:
the metal clip is a first metal clip;
the method further comprises attaching second and third clip portions of a second metal clip to respective conductive features of the substrate with a first clip portion of the second metal clip above and spaced apart from the first portion of the first plate, the first clip portion of the second metal clip extending between the second and third clip portions of the second metal clip, and with the second metal clip spaced apart from the first metal clip; and
forming the package structure encloses the second metal clip in the magnetic molding compound.

16. The method of claim 12, wherein removing the portion of the package structure to expose the second portion of the first plate includes performing a cutting process (1200) to form a recess that extends into a side of the package structure and exposes the second portion of the first plate.

17. The method of claim 16, wherein thermally coupling the second plate to the exposed surface of the second portion of the first plate includes soldering the second plate to the exposed surface of the second portion of the first plate in the recess.

18. The method of claim 17, wherein soldering the second plate to the exposed surface of the second portion of the first plate includes:
forming solder in the recess;
attaching the second plate to the package structure with a portion of the second plate engaging the solder in the recess; and
reflowing the solder.

19. The method of claim 12, wherein removing the portion of the package structure to expose the second portion of the first plate includes performing a laser ablation process to form a recess that extends into a side of the package structure and exposes the second portion of the first plate.

20. The method of claim 12, wherein attaching the first portion of the first plate to the second side of the semiconductor die includes electrically coupling the first portion of the first plate to the second side of the semiconductor die.
